(19) United States
(12) Patent Application Publication
(10) Pub. No.: US 2011/0123934 A1
(43) Pub. Date: May 26, 2011

(54) SCANNING EXPOSURE APPARATUS

(75) Inventor: Tadahiro Asaishi, Utsunomiya-shi (JP)

(73) Assignee: CANON KABUSHIKI KAISHA, Tokyo (JP)

(21) Appl. No.: 12/948,997

(22) Filed: Nov. 18, 2010

(30) Foreign Application Priority Data
Nov. 20, 2009 (JP) 2009-265233

(51) Int. Cl. G03F 7/20; G03B 27/72

(52) U.S. Cl. 430/322; 355/71

(57) ABSTRACT

A scanning exposure apparatus includes a light source, a stage configured to move while having a substrate mounted thereon, a control unit configured to control the light source and the stage such that the substrate is exposed to radiant energy while the speed of the stage is changed, a filter having a transmittance distribution according to a change in speed of the stage and being disposed so as to be insertable into a light path for exposure, and a driving unit configured to scan the filter in synchronization with the scanning of the stage.

### BACKGROUND OF THE INVENTION

1. Field of the Invention

The present invention relates to scanning exposure apparatuses.

2. Description of the Related Art

Exposure apparatuses are used in processes for manufacturing devices such as semiconductor devices and liquid-crystal display devices. The exposure apparatuses transfer circuit patterns formed on reticles (originals) onto wafers (substrates). Although there are various types of exposure apparatuses, scanning exposure apparatuses, which synchronously scan wafer stages on which wafers are mounted and reticle stages on which reticles are mounted during exposure, using pulsed light sources are in the mainstream.

In such scanning exposure apparatuses using pulsed light sources, it is important to appropriately set time to emit pulsed light from the pulsed light sources, the interval of the pulsed light emission, and the scanning speed of the wafer stages so that the amount of exposure light incident on the wafers is fixed and unevenness of exposure is reduced.

FIG. 7A illustrates the speed of a reticle stage during scanning exposure, FIG. 7B illustrates the speed of a wafer stage during the same period, and FIG. 7C illustrates the oscillation frequency of a pulsed light source during the same period in a known exposure apparatus.

As shown in FIG. 7C, pulses are emitted at a fixed oscillation frequency while the speed of the reticle stage and that of the wafer stage are both fixed so that the amount of exposure is made uniform. That is, the pulsed light emission is not used for exposure during acceleration and deceleration.

Exposure is also performed while wafer stages are accelerated and decelerated in Japanese Patent Laid-Open Nos. 09-223662 and 2003-133216. Specifically, exposure of wafers to radiant energy is made uniform by changing the amount of exposure per unit time in response to the speed of wafer stages. With this, throughput can be improved compared with the case shown in FIGS. 7A to 7C.

In order to change the amount of exposure as described above, the interval of the pulsed light emission or the intensity of light emitted from the light source can be changed. For example, when the maximum speed of a wafer stage is 500 mm/sec and the minimum speed is 50 mm/sec during exposure, the emission interval or the emission intensity needs to be changed in a range of one time to ten times.

However, the variable range of the emission interval of the pulsed light or the emission intensity of the light source is often limited for various reasons. For example, the variable range is limited in excimer lasers by the following reasons.

### (1) Limitation of Variable Range of Emission Interval

Important characteristics for optical performance of exposure light include central wavelength stability, line width stability, and energy stability. These characteristics change in accordance with the emission interval of pulsed light. For example, when the emission interval is significantly changed, energy stability may be reduced under the influence of gas inside chambers that accommodate light sources. Moreover, line width stability may be reduced at specific emission intervals under the influence of acoustic waves inside the chambers. For these reasons, excimer lasers are designed to satisfy predetermined optical performance when the emission interval is in a predetermined limited range.

### (2) Limitation of Variable Range of Emission Intensity

The emission intensity of current excimer lasers can be changed only in a range of about ±15% with respect to the rated emission intensity. This is because the excitation state cannot be kept stable inside the chambers and the energy stability for each pulse is reduced when the emission intensity is too low, and optical elements inside the chambers may be damaged and the lifetime thereof is reduced when the emission intensity is too high.

These limitations disadvantageously cause insufficient reduction in the unevenness of exposure.

### SUMMARY OF THE INVENTION

The present invention provides an exposure apparatus of which throughput is improved and of which exposure unevenness is reduced.

According to an aspect of the present invention, a scanning exposure apparatus includes a light source, a stage configured to move while having a substrate mounted thereon, a control unit configured to control the light source and the stage such that the substrate is exposed to radiant energy while the speed of the stage is changed, a filter having a transmittance distribution according to a change in speed of the stage and being disposed so as to be insertable into a light path for exposure, and a driving unit configured to scan the filter in synchronization with the scanning of the stage.

Further features of the present invention will become apparent from the following description of exemplary embodiments with reference to the attached drawings.

### BRIEF DESCRIPTION OF THE DRAWINGS

FIGS. 1A and 1B illustrate the transmittance distribution of a neutral-density filter.

FIGS. 2A and 2B illustrate the speed of a stage and the illuminance, respectively, during exposure.

FIG. 3 is a schematic view of a scanning exposure apparatus.

FIG. 4 illustrates an exposure sequence of the exposure apparatus.

FIGS. 5A to 5D illustrate parameters during scanning exposure.

FIG. 6 illustrates a modification.

FIGS. 7A to 7C illustrate the speed of stages during exposure.

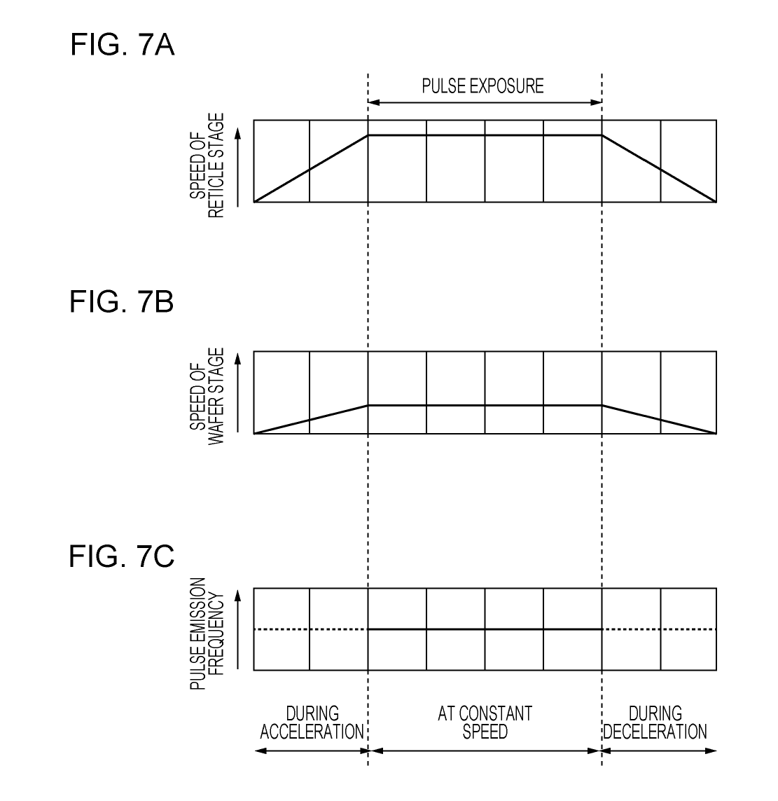

### DESCRIPTION OF THE EMBODIMENTS

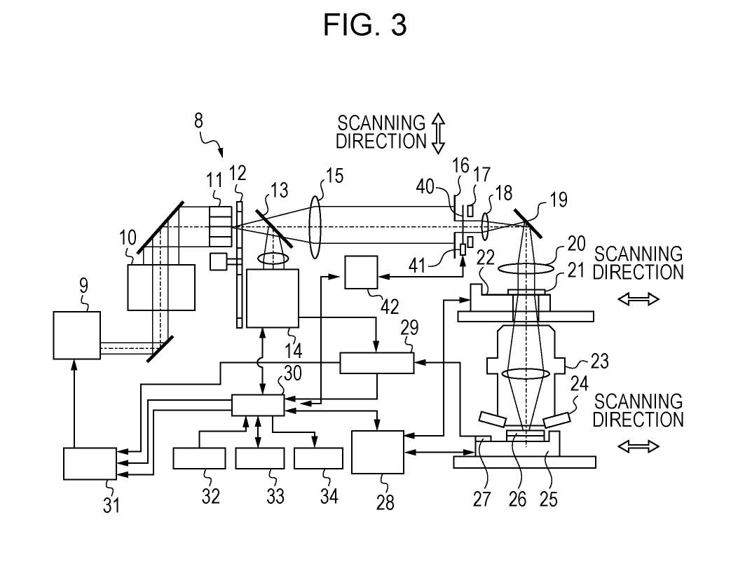

FIG. 3 is a schematic view of a scanning exposure apparatus according to an exemplary embodiment.

The exposure apparatus includes, for example, an illumination optical system 8 that illuminates a reticle (original) 21 using a light beam emitted from a light source 9, a reticle stage 22 that moves while having the reticle 21 mounted thereon, a projection optical system 23, and a wafer stage 25 that moves while having a wafer (substrate) 26 mounted thereon.

An excimer laser is used as the light source 9, and a light-source control unit 31 controls the light source 9. The illumination optical system 8 includes, for example, a beam-shaping optical system 10, an optical integrator 11, an aperture turret 12, a half mirror 13, condenser lenses 15 and 18, an adjustable slit 16, a masking blade 17, a neutral-density filter 40, and a mirror 19.

The light beam emitted from the light source 9 is shaped into a predetermined shape by the beam-shaping optical system 10, and guided to the incident surface of the optical integrator. The optical integrator 11 includes a plurality of minute lenses, and forms a large number of secondary light sources in the vicinity of the emergent surface thereof. A light beam emitted from the optical integrator 11 passes through apertures embedded in the aperture turret 12. The apertures limit the size of the surface of the secondary light sources. Illumination mode numbers are assigned to the apertures of the aperture turret 12. The apertures include, for example, aperture stops, of which circular aperture areas vary from each other, prepared for setting a plurality of coherence factors σ; ring-shaped apertures prepared for annular illumination; and quadrupole apertures. A required aperture is selected from the above-described apertures, and inserted into the light path. The light beam passing through the aperture turret 12 is partially reflected from the half mirror 13, and guided to a photoelectric conversion device 14.

The light beam passing through the half mirror 13 is guided to the adjustable slit 16 and the masking blade 17 through the condenser lens 15. The adjustable slit 16 partially blocks the light beam, and forms a rectangular or arc-shaped slit beam. The masking blade 17 includes a movable light-shielding portion, and synchronously scans the light-shielding portion during scanning exposure so that areas other than patterns to be exposed to radiant energy on the reticle are prevented from being exposed. Moreover, the neutral-density filter 40 is disposed in the vicinity of the adjustable slit 16 and the masking blade 17. The neutral-density filter 40 will be described below in detail. In FIG. 3, the direction corresponding to the scanning direction of the wafer stage is also indicated as “scanning direction”.

The illuminance and the incident angle of the slit beam are made uniform while the slit beam passes through the condenser lens 18, the mirror 19, and the lens 20, and the beam forms an image on the reticle 21. Herein, the pattern surface of the reticle is an optically conjugate plane of the masking blade 17. The slit beam passing through the reticle 21 forms an image on the wafer 26 via the projection optical system 23. Herein, the surface of the wafer 26 is an optically conjugate plane of the pattern surface of the reticle 21. Moreover, a photoresist layer (a layer on which photoresist is applied) is formed on the surface of the wafer 26. During exposure, the wafer stage 25 on which the wafer 26 is mounted and the reticle stage 22 on which the reticle 21 is mounted are synchronously scanned, thereby the pattern of the reticle 21 is transferred onto the wafer 26. The wafer stage and the reticle stage are controlled by a stage control unit 28. The control units 28 and 31 allow exposure of the wafer while the speeds of the stages are changed.

Moreover, a focus detection system 24 for detecting the surface position of the wafer 26 is disposed in the vicinity of the projection optical system 23. The focus detection system 24 includes a light-emitting portion that emits light to the surface of the wafer 26 and a light-receiving portion that receives light reflected from the surface of the wafer 26, and detects the surface position of the wafer 26 in the Z direction. The wafer stage 26 is driven such that the surface of the wafer 26 corresponds to the image plane of the projection optical system 23 during exposure on the basis of the output from the focus detection system 24.

Another photoelectric conversion device 27 is mounted on the wafer stage 25. The correlation between the photoelectric conversion device 27 and the photoelectric conversion device 14 is acquired before exposure of the wafer, and the amount of light on the wafer is monitored during exposure on the basis of the output from the photoelectric conversion device 14 and the correlation. These computation processes are performed by an exposure control unit 29 that performs control relating to the amount of exposure.

A main control unit 30 that controls the entire exposure apparatus can communicate with the control units 31, 28, and 29. Furthermore, the main control unit can communicate with an input device 32, a storage device 33, and a display device 34. The main control unit 30 determines exposure conditions on the basis of information regarding the accumulated amount of exposure input to the input device 32 or stored in the storage device 33. The information regarding the accumulated amount of exposure includes, for example, an exposure amount profile indicating the relationship between the moving distance of the stage and the accumulated amount of exposure light to be incident on the wafer surface, a required accuracy of the accumulated amount of exposure, and a beam-limiting form. The exposure conditions to be calculated include, for example, the maximum scanning speed of the wafer stage 25, the speed profile corresponding to a shot, the oscillation frequency of the light source, the number of pulses emitted from the light source, the number of exposure-starting pulses, and the driving target value of the adjustable slit. Among the above-described exposure conditions, the oscillation frequency of the light source 9, the number of pulses emitted from the light source 9, and the number of exposure-starting pulses are set in the light-source control unit 31, and the scanning speed of the wafer stage 25 is set in the stage control unit 28. Input to the input device can be performed using either a man-machine interface or a media interface.

The light-source control unit 31 controls the oscillation frequency of the light source 9 and the laser output so as to achieve a desired amount of exposure on the basis of the exposure conditions sent from the main control unit 30 and a signal regarding the amount of exposure transmitted from the exposure control unit 29.

Next, the neutral-density filter 40 will be described.

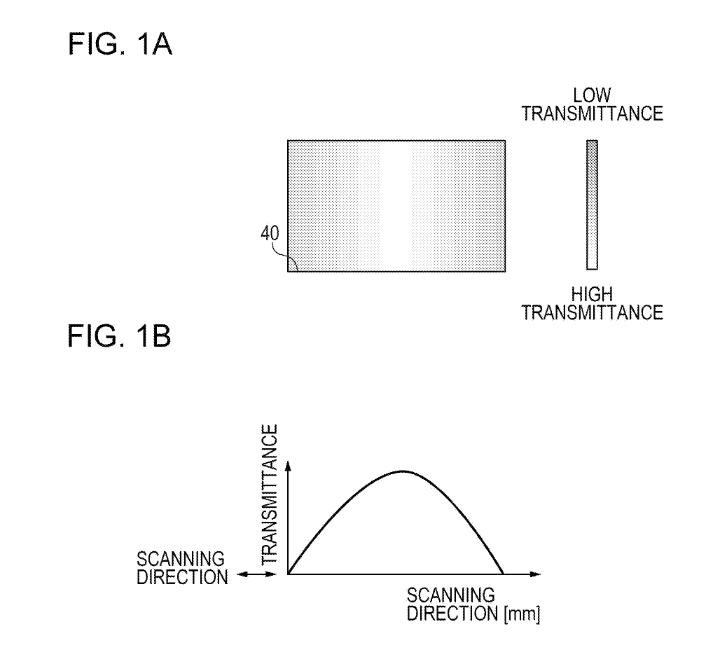

FIG. 1A illustrates the neutral-density filter 40. The neutral-density filter 40 has a transmittance distribution according to a change in speed of the stage, and is disposed so as to be insertable into the light path for exposure. That is, the neutral-density filter 40 has a transmittance distribution varying in the scanning direction as shown in FIG. 1B, and the transmittance is lower in end portions than in the central portion. The neutral-density filter 40 is scanned by a driving unit 41 in synchronization with the scanning of the wafer stage 25. The driving unit 41 can include well-known units such as a linear motor and a rotary motor using ball screws. Moreover, the driving unit 41 is controlled by a filter control unit 42, and the filter control unit 42 can communicate with the main control unit 30.

When the illuminance is I(t) W/m², the width of the slit beam is W mm, and the scanning speed is V(t) mm/s, the accumulated amount of exposure D(t) J/m² on the wafer is expressed by Equation (1).

D(t)=I(t)×W/V(t) (1)

Since the neutral-density filter 40 having the transmittance distribution varying in the scanning direction as described above is scanned in synchronization with the wafer stage according to this exemplary embodiment, the transmittance of light from the light source to the wafer can be expressed as T(t).

Therefore, when the amount of exposure per pulse is E(t) J/m², the oscillation frequency of the laser is f(t) Hz, and the transmittance of light from the light source to the wafer is T(t), the illuminance can be expressed by the following equation.

I(t)=E(t)×f(t)×T(t) (2)

Equations (1) and (2) lead to the following equation.

D(t)=E(t)×f(t)×T(t)×W/V(t) (3)

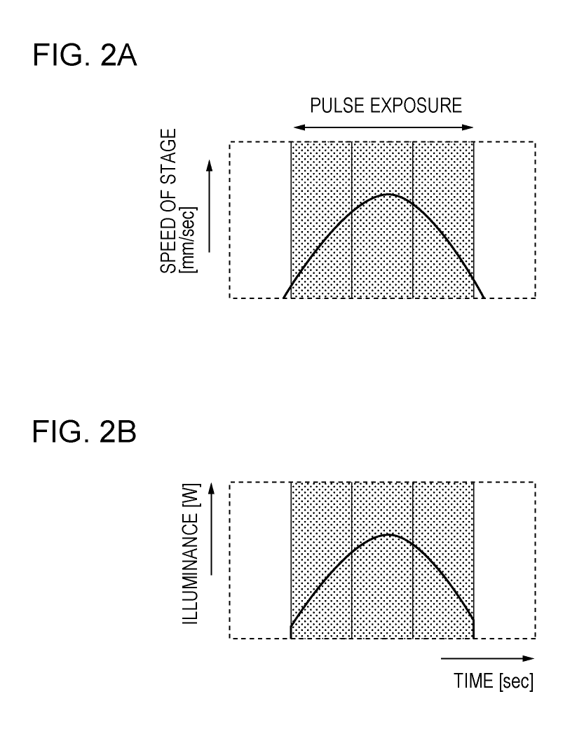

According to this exemplary embodiment, exposure is also performed while the wafer stage is accelerated and decelerated in order to improve the throughput. Therefore, the transmittance distribution and the scanning speed (target speed) of the neutral-density filter 40 are set such that the illuminance I(t) is in proportion to the scanning speed (target speed) of the wafer stage so as to achieve a uniform accumulated amount of exposure. Specifically, the transmittance distribution and the scanning speed of the filter are set such that the illuminance as shown in FIG. 2B is achieved in response to the scanning speed of the wafer stage as shown in FIG. 2A. With this, variations in the accumulated amount of exposure during one shot are reduced.

Moreover, the exposure apparatus further includes a holder that stores additional neutral-density filters of which transmittance distributions are different from each other and a hand (insertion unit) that inserts one of the neutral-density filters taken out of the holder into the light path. The structure of the insertion unit is not specifically limited, and the driving unit 41 can have the insertion function. The plurality of neutral-density filters that are selectively insertable into the light path as described above can change the transmittance distribution. The location of the neutral-density filter 40 is not limited to that in FIG. 3, and the filter can be disposed in the vicinity of the reticle. According to this exemplary embodiment, the illuminance is made proportional to the scanning speed by finely adjusting the amount E(t) of light per pulse, the oscillation frequency F(t), and the width W(t) of the exposure light.

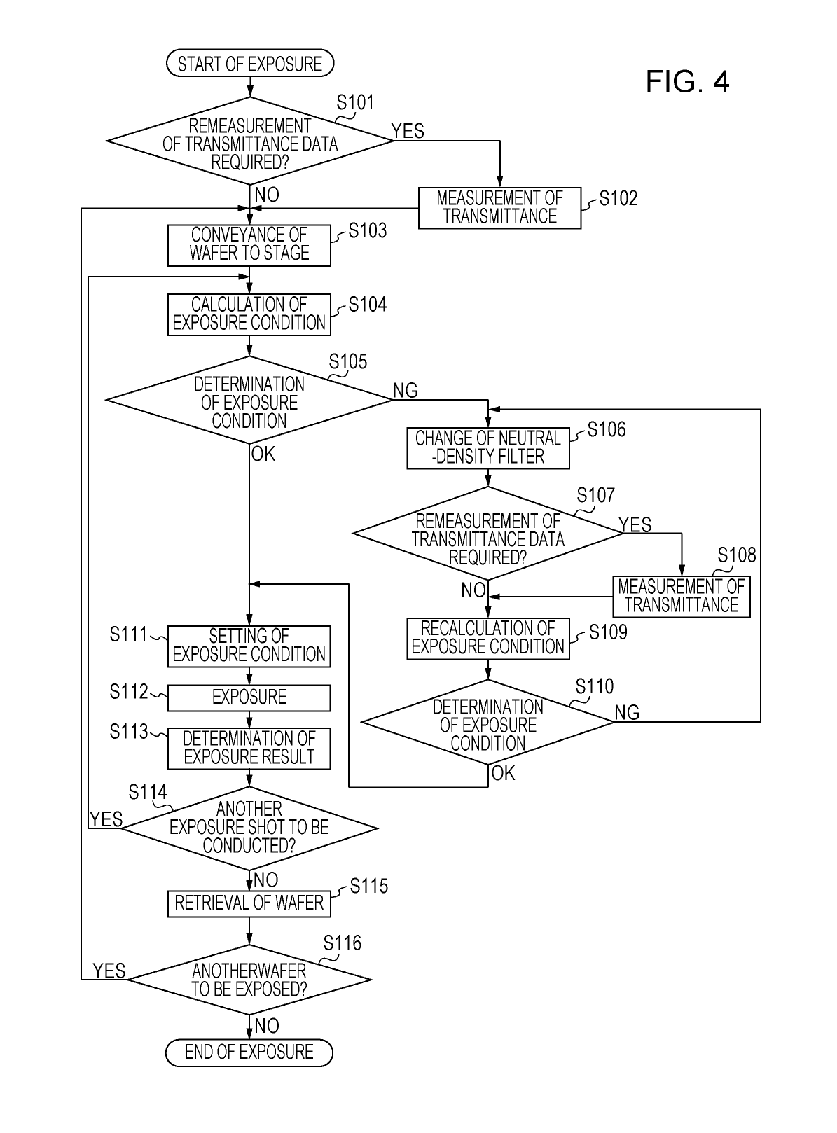

Next, an exposure sequence according to this exemplary embodiment will be described. FIG. 4 is a flow chart illustrating the exposure sequence.

In Step S101, it is determined whether or not the transmittance of the neutral-density filter 40 needs to be measured. The main control unit determines that the transmittance needs to be measured when the storage device 33 has no data regarding the transmittance, and the process proceeds to Step S102. When the storage device 33 has data regarding the transmittance, it is determined whether or not the transmittance needs to be measured in accordance with a predetermined condition. For example, the transmittance can be measured when a predetermined period has elapsed since the transmittance was measured the last time. When it is determined that the transmittance does not need to be measured, the process proceeds to Step S103. This determination can be performed by users instead of being automatically performed by the exposure apparatus.

In Step S102, the transmittance of the neutral-density filter 40 is measured. The transmittance distribution is measured using the output from the photoelectric conversion device 27 by illuminating the photoelectric conversion device 27 with light at an illuminance I while the neutral-density filter 40 and the wafer stage are scanned at predetermined speeds. The measured results are stored in the storage device 33. Subsequently, the process proceeds to Step S103.

In Step S103, a wafer is carried onto the wafer stage. Various processes such as pre-alignment, alignment, and focus measurement are performed.

In Step S104, exposure conditions are calculated. Specifically, the maximum scanning speed, the speed profile corresponding to a shot, and the number of exposure-starting pulses are calculated on the basis of the accumulated amount of exposure, the illuminance, and the width of the exposure light set in advance. When the maximum scanning speed exceeds the upper limit determined by the apparatus (for example, by driving mechanisms or control systems thereof) at this moment, the maximum scanning speed is set so as not to exceed the upper limit by adjusting and reconfiguring the illuminance of the apparatus. Next, the illuminance and the speed of the wafer stage are scaled so that the deviation is determined.

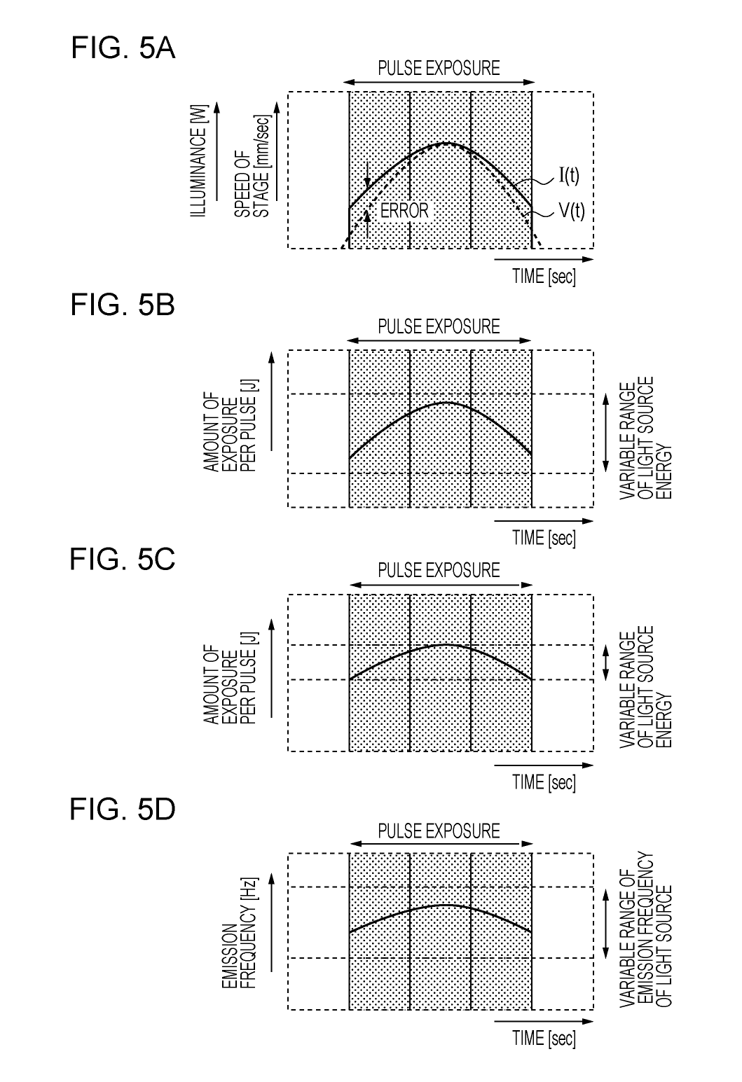

For example, as shown in FIG. 5A, when the illuminance is higher than the speed of the wafer stage in the vicinity of the start and the end of exposure, exposure is excessively performed in the vicinity of the start and the end of exposure. Therefore, any one of the amount of exposure per pulse, the oscillation frequency, and the width of the exposure light is adjusted in a variable range so that the illuminance in the vicinity of the start and the end of exposure is reduced. FIG. 5B illustrates an example in which the amount of exposure per pulse is adjusted. The illuminance can be adjusted by using two or more of the amount of exposure per pulse, the oscillation frequency, and the width of the exposure light.

In Step S105, determination of the exposure conditions is performed. Specifically, it is determined whether or not the deviation between the illuminance and the speed of the wafer stage is smaller than a predetermined value. When the deviation is smaller than the predetermined value, the process proceeds to Step S111, and the exposure conditions are set. When the deviation is larger than the predetermined value, the process proceeds to Step S106.

In Step S106, the filter control unit 42 changes the neutral-density filter. Herein, it is preferable that a neutral-density filter having a most correlative transmittance distribution be selected to be used as the neutral-density filter 40 on the basis of the speed profile of the wafer stage calculated in Step S104.

In Step S107, it is determined whether or not the transmittance of the neutral-density filter needs to be measured. The main control unit determines that the transmittance needs to be measured when the storage device 33 has no data regarding the transmittance, and the process proceeds to Step S108. When the storage device 33 has data regarding the transmittance, it is determined whether or not the transmittance needs to be measured in accordance with a predetermined condition. For example, the transmittance can be measured when a predetermined period has elapsed since the transmittance was measured the last time. When it is determined that the transmittance does not need to be measured, the process proceeds to Step S109. This determination can be performed by users instead of being automatically performed by the exposure apparatus.

In Step S108, the transmittance of the neutral-density filter 40 is measured. The transmittance distribution is measured using the output from the photoelectric conversion device 27 by illuminating the photoelectric conversion device 27 with light at an illuminance I while the neutral-density filter 40 and the wafer stage are scanned at predetermined speeds. The measured results are stored in the storage device 33. Subsequently, the process proceeds to Step S109.

In Step S109, exposure conditions are calculated. Specifically, the maximum scanning speed, the speed profile corresponding to a shot, and the number of exposure-starting pulses are calculated on the basis of the accumulated amount of exposure, the illuminance (for example, the oscillation frequency and the amount of light per pulse), and the width of the exposure light set in advance. When the maximum scanning speed exceeds the upper limit determined by the apparatus (for example, by the driving mechanisms or the control systems thereof) at this moment, the maximum scanning speed is set so as not to exceed the upper limit by adjusting and reconfiguring the illuminance of the apparatus. Next, the illuminance and the speed of the wafer stage are scaled so that the deviation is determined.

In Step S110, determination of the exposure conditions is performed. Specifically, it is determined whether or not the deviation between the illuminance and the speed of the wafer stage is smaller than a predetermined value. When the deviation is smaller than the predetermined value, the process proceeds to Step S111, and the exposure conditions are set. When the deviation is larger than the predetermined value, the process returns to Step S106.

In Step S111, the set exposure conditions are transmitted to the control units. The oscillation frequency, the amount of light per pulse, and the number of emission pulses of the light source are sent to the light-source control unit, and the maximum scanning speed and the speed profile are sent to the stage control unit.

In Step S112, exposure is performed on the basis of the set exposure conditions. In Step S113, determination of exposure results is performed for each shot. Specifically, the quality of light (for example, the performance of the wavelength and the line width of the laser) during exposure and the amount of exposure for each shot are examined. During examination of the light quality, errors and variations for each pulse are calculated by comparing the wavelength and the line width of the laser monitored during exposure with the set values. When the calculated values exceed the set values, it is determined that an exposure error has occurred during the shot. Moreover, during examination of the amount of exposure, errors and variations for each pulse are calculated by comparing the output from the photoelectric conversion device 14 monitored during exposure and the set value. When the calculated values exceed the set values, it is determined that an exposure error has occurred during the shot. When the above-described exposure error occurs, the operator is informed of the error information. In Step S114, the process returns to Step S104 when there is another exposure shot to be conducted, or the process proceeds to Step S115 when all the exposure shots have been conducted. In Step S115, the wafer is retrieved from the wafer stage. In Step S116, when there is another wafer to be exposed, the process returns to Step S103.

In the above-described exemplary embodiment, the configuration of the control units can be changed as appropriate. For example, a part of or all the functions of the above-described control units can be provided for the main control unit, or conversely, a part of the functions of the main control unit can be provided for the other control units.

### Modification

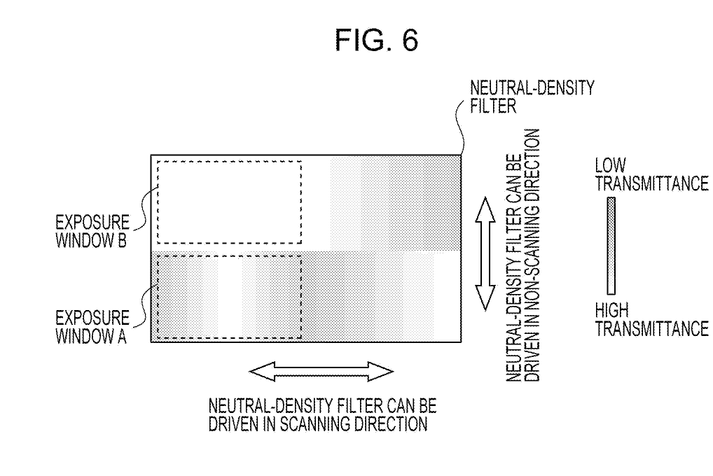

Instead of the above-described structure, a neutral-density filter as shown in FIG. 6 can be prepared. This neutral-density filter has a transmittance distribution varying in both the scanning direction and the non-scanning direction, and the size thereof is large compared with the shot size. With this structure, the transmittance can be variously changed using only one neutral-density filter by driving the neutral-density filter in the scanning direction and the non-scanning direction. For example, the neutral-density filter is driven such that exposure light passes through an area B when the scanning speed of the wafer stage is fixed and such that exposure light passes through an area A when the scanning speed changes.

### Method of Manufacturing Device

Next, a method of manufacturing a device (semiconductor device, liquid-crystal display device, and the like) according to an exemplary embodiment of the present invention will be described. A semiconductor device is manufactured through a front-end process in which an integrated circuit is formed on a wafer and a back-end process in which an integrated circuit chip formed on the wafer in the front-end process is completed as a product. The front-end process includes a step of exposing a wafer on which photoresist is applied to radiant energy using the above-described exposure apparatus and a step of developing the exposed wafer. The back-end process includes an assembly step (dicing and bonding) and a packaging step (sealing). A liquid-crystal display device is manufactured through a process of forming a transparent electrode. The process of forming the transparent electrode includes a step of applying photoresist on a glass substrate on which a transparent electroconductive film is evaporated, a step of exposing the glass substrate on which the photoresist is applied to radiant energy using the above-described exposure apparatus, and a step of developing the exposed glass substrate. In accordance with the method of manufacturing the device according to this exemplary embodiment, devices having a quality higher than that of known devices can be manufactured.

### Other Embodiments

Aspects of the present invention can also be realized by a computer of a system or apparatus (or devices such as a CPU or MPU) that reads out and executes a program recorded on a memory device to perform the functions of the above-described exemplary embodiment(s), and by a method, the steps of which are performed by a computer of a system or apparatus by, for example, reading out and executing a program recorded on a memory device to perform the functions of the above-described exemplary embodiment(s). For this purpose, the program is provided to the computer for example via a network or from a recording medium of various types serving as the memory device (e.g., computer-readable medium).

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-265233, filed Nov. 20, 2009, which is hereby incorporated by reference herein in its entirety.

What is claimed is:

1. A scanning exposure apparatus comprising:
a light source;
a stage configured to move while having a substrate mounted thereon;
a control unit configured to control the light source and the stage such that the substrate is exposed to radiant energy while the speed of the stage is changed;
a filter having a transmittance distribution according to a change in speed of the stage and being disposed so as to be insertable into a light path for exposure; and
a driving unit configured to scan the filter in synchronization with the scanning of the stage.

2. The exposure apparatus according to claim 1, wherein
the transmittance of the filter is lower in an end portion of the filter than in a central portion of the filter in a scanning direction.

3. The exposure apparatus according to claim 1, wherein
the driving unit is controlled on the basis of a target speed of the stage.

4. The exposure apparatus according to claim 1, further comprising:
another filter; and
an insertion unit configured to selectively insert one of the filters into the light path.

5. The exposure apparatus according to claim 4, wherein
the insertion unit selects a filter having a transmittance distribution that is most correlative to the target speed of the stage from the filters on the basis of the target speed of the stage and the transmittance distributions of the filters, and inserts the selected filter into the light path.

6. The exposure apparatus according to claim 1, wherein
the filter has a plurality of areas of which transmittance distributions vary from each other, and
the insertion unit selects an area having a transmittance distribution that is most correlative to the target speed of the stage from the areas on the basis of the target speed of the stage and the transmittance distributions of the areas, and inserts the area portion into the light path.

7. A method of manufacturing a device utilizing an exposure apparatus including,
a light source;
a stage configured to move while having a substrate mounted thereon;
a control unit configured to control the light source and the stage such that the substrate is exposed to radiant energy while the speed of the stage is changed;
a filter having a transmittance distribution according to a change in speed of the stage and being disposed so as to be insertable into a light path for exposure; and
a driving unit configured to scan the filter in synchronization with the scanning of the stage;
the method comprising:
exposing a substrate to radiant energy using the exposure apparatus; and
developing the exposed substrate.
